(19) United States
(12) Patent Application Publication
(10) Pub. No.: US 2024/0414874 A1
(43) Pub. Date: Dec. 12, 2024

(54) ROBOT CONTROLLER CABINET AND ROBOT COMPRISING SUCH A CABINET

(71) Applicant: STAUBLI FAVERGES, Faverges-Seythenex (FR)

(72) Inventors: Corentin Bouchet, Faverges-Seythenex (FR); Germano Anni, Manerbio (bs) (IT); Benoit Salleyrette, Doussard (FR)

(21) Appl. No.: 18/736,824

(22) Filed: Jun. 7, 2024

(30) Foreign Application Priority Data
Jun. 12, 2023 (FR) 2305899

(51) Int. Cl. H05K 7/20; B25J 9/00

(52) U.S. Cl. CPC H05K 7/20154; B25J 9/00

(57) ABSTRACT

Robot controller cabinet and robot including such a cabinet. The disclosure relates to a robot controller cabinet including a chamber. First and second electronic units include an electronic component with a high heat flux and with a moderate heat flux, respectively. A cooling channel includes a fan and an inlet provided on a front side of the cabinet. An air-to-component heat exchanger supporting a cooling element. The disclosure also relates to an air-air cross-flow exchanger arranged in the channel and includes a first cooling circuit with an inlet and an outlet passing through a bottom panel of the chamber and second cooling circuit with a parallel inlet and outlet. The inlet is opposite the inlet of the channel. A fan, generating in the first cooling circuit an airflow perpendicular to an airflow generated in the second cooling circuit by the fan of the channel.

### FIELD

The present invention relates to a robot controller cabinet and a robot comprising such a cabinet.

### BACKGROUND

To ensure the correct operation of all the components, robot controller cabinets, e.g. known from EP3079451A1, comprise cooling elements in direct thermal contact with the electronic components and with a cooling channel. On the other hand, the cabinets separate, within two distinct chambers, the electronic components that generate heat and the electronic components that have to operate within a certain temperature range.

The cabinets separating the electronic components into two different chambers have the disadvantage of being quite expensive and bulky.

### SUMMARY

The invention relates to the field of industrial robots which generally comprise a robot arm, a robot controller and transmission cables for connecting the robot arm to the controller.

The robot arm generally consists of a plurality of articulated elements movable relative to one another by electric motors equipped with sensors apt to provide the position thereof. The robot controller gathers, in a cabinet distinct from the robot arm, all the electronic components apt to determine and provide control setpoints to the robot arm.

The robot controller cabinet has two features which are to contain the electronic components needed for the operation of the robot arm and to ensure good operating conditions for the electronic components.

Indeed, some electronic components needed for controlling the robot arm, such as amplifiers, produce a large amount of heat during use, while other components such as processors only function properly when the temperature in the cabinet is not too high.

The invention aims to remedy drawbacks by providing a new robot controller cabinet that allows for the optimal operation of electronic components, while being compact.

The subject matter of the invention is a robot controller cabinet comprising a chamber defined by a top panel, a bottom panel, two lateral panels, a back panel, and a front panel placed opposite the back panel and defining a front side of the robot controller cabinet, at least one first electronic unit mounted on the rear panel of the chamber, inside the chamber, and comprising at least one electronic component with a high heat flux, at least one second electronic unit mounted on one or more of the lateral panels or the top panel, inside the chamber, and comprising at least one electronic component with a moderate heat flux. The robot controller cabinet also comprises a cooling channel having an inlet opening and at least one fan apt to draw in outside air through an inlet opening of the cooling channel and to discharge same outwardly through an outlet opening located at the end opposite the inlet opening of the cooling channel. The cabinet further comprises at least one air-to-component heat exchanger associated with a first electronic unit and accommodating, on a first side, at least one electronic component with a high heat flux and supporting, on a second side, at least one cooling element arranged in the cooling channel. According to the invention, the cooling channel comprises a first portion defined between the bottom panel of the chamber and an outer parallel panel defining a bottom of the robot controller cabinet and a second portion contiguous to the first portion, located between the rear panel of the chamber and an outer parallel panel defining a rear side of the robot controller cabinet. The inlet opening of the cooling channel is provided on the front side of the cabinet. An air-air cross-flow exchanger is arranged in the cooling channel and comprises a first cooling circuit having an inlet opening through the bottom panel of the chamber and an outlet opening through the bottom panel of the chamber and a second cooling circuit having an opening inlet opposite the inlet opening of the cooling channel and an outlet opening parallel to the inlet opening of the second cooling circuit, being arranged at the opposite end of the air-air cross-flow exchanger and opening into the cooling channel. At least one fan located inside the chamber opposite the inlet opening or the outlet opening of the first cooling circuit of the air-air cross-flow heat exchanger generates, in the first cooling circuit, an airflow perpendicular to an airflow generated in the second cooling circuit by the cooling channel fan.

By means of to the invention, the robot controller cabinet consists of a single chamber with both components with a high heat flux and components with a moderate heat flux while ensuring through the air-air cross-flow heat exchanger that the heat produced by the components with a high heat flux affects in a limited way the components with a moderate heat flux that cannot function properly when the temperature inside the chamber is too high. The robot controller cabinet is compact because same comprises a single chamber to accommodate all electronic components.

As defined by the present invention, an electronic component with a high heat flux is an electronic component which dissipates a high rate of heat flow given the dimensions thereof. Since such high power dissipation is concentrated on a small quantity of material, the dissipation leads to a significant increase in the temperature of the component. An electronic component with a high heat flux dissipates e.g. a rate of heat flow ranging from 20 Watt to 200 Watt. Moreover, an electronic component with a moderate heat flux is an electronic component that dissipates a low rate of heat flow but the temperature increase of which has to be limited for the component to function properly, i.e. which dissipates e.g. a rate of heat flow of less than 35 Watt.

According to other advantageous aspects of the invention, the robot controller cabinet comprises one or a plurality of the following features, taken individually or according to all technically possible combinations:

The cooling channel fan is placed downstream of the air-air cross-flow exchanger, upstream of the air-to-component heat exchanger and in the second portion of the cooling channel.

The first electronic unit is an amplifier and the component with a high heat flux is a switching module, preferably an insulated-gate bipolar transistor.

The first electronic unit is a power supply and the component with a high heat flux is an insulated-gate field effect transistor or a thyristor or a DC-DC converter element that converts a DC source from a specified level of voltage to another different level of voltage.

The second electronic unit is a computing unit and the component with a moderate heat flux is a processor, or the second electronic unit is a filtering unit and the component with a moderate heat flux is a passive filtering component.

The robot controller cabinet comprises a braking resistor, mounted on the rear panel of the chamber in the cooling channel downstream of the air-to-component heat exchanger, configured to dissipate excess energy produced by the first electronic unit.

The outlet opening of the cooling channel is provided on the rear side of the robot controller cabinet.

The second electronic unit is arranged inside a first rack unit supported by the top panel of the chamber, the first rack unit comprising a first opening, arranged opposite one lateral side of the chamber, and a second opening arranged opposite the other lateral side of the chamber.

A lateral panel of the chamber comprises an opening closed by a door and the second electronic unit is placed on the top panel of the chamber and/or is supported by the door of the lateral panel.

The invention further relates to a multi-axis robot comprising a robot arm articulated with at least two degrees of freedom, a robot controller cabinet as mentioned hereinabove, and cables connecting the robot arm to the robot controller cabinet.

### BRIEF DESCRIPTION OF THE DRAWINGS

The invention will be clearer upon reading the following description, given only as an example, but not limited to, and making reference to the drawings wherein:

FIG. 1 is a perspective view of a multi-axis robot according to the invention comprising an articulated arm and a robot controller cabinet also according to the invention;

FIG. 2 is a perspective cutaway view with of the robot controller cabinet shown in FIG. 1;

FIG. 3 is a perspective rear view of the robot controller cabinet shown in FIG. 2;

FIG. 4 is a sectional view along the plane P1 visible in FIG. 2;

FIG. 5 is a sectional view along the plane P2 visible in FIG. 2;

FIG. 6 is a perspective view of an air-air cross-flow exchanger of the robot controller cabinet shown in FIGS. 2 to 5, insert A) illustrates a first air cooling circuit and insert B) illustrates a second air cooling circuit;

FIG. 7 is a perspective view of an air-to-component heat exchanger and a part of the structure of the robot controller cabinet shown in FIGS. 2 to 5; and

FIG. 8 is a perspective view, similar to the view shown in FIG. 2, of a robot controller cabinet according to a second embodiment of the invention.

### DESCRIPTION

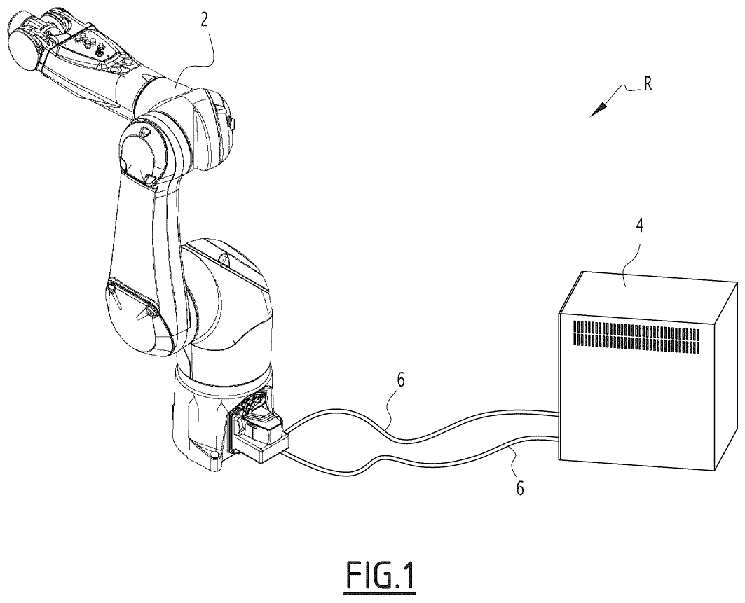

The robot R shown in FIG. 1 comprises a robot arm 2 consisting of a plurality of articulated sections movable relative to one another by means of electric motors (not shown). The robot R also comprises a robot controller cabinet 4 that contains electronics units that implement:
a computing unit apt to determine motor control setpoints from an application program, amplifiers apt to generate the currents in the motors from the motor control setpoints and the position information of the motors of the robot arm,
a power supply apt to supply the amplifiers and the computing unit with the needed voltages from the mains voltage.

The robot R further comprises electrical cables 6 that connect the robot arm 2 to the robot controller cabinet 4 and transmit currents to the motors and the position signals of the motors of the robot arm 2 to the robot controller cabinet 4.

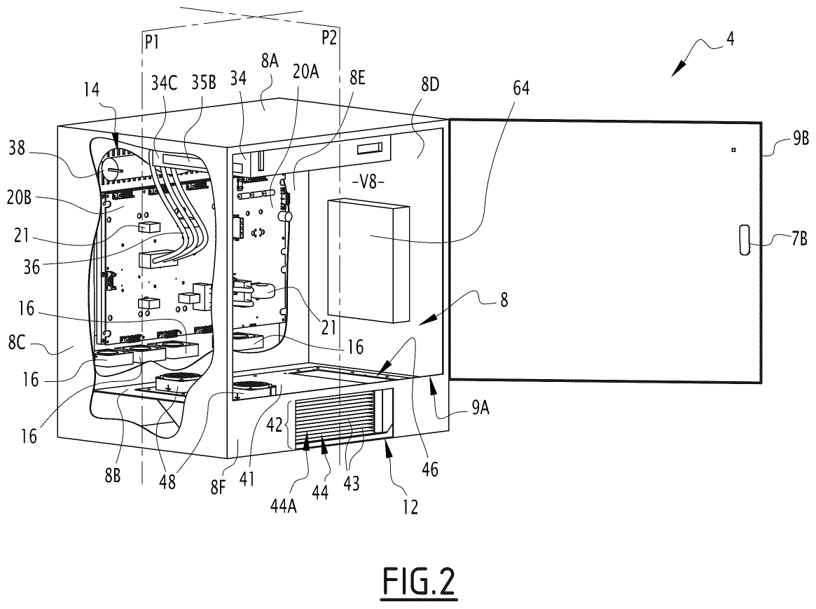

The robot controller cabinet 4 is shown in detail in FIGS. 2 to 5. The robot cabinet 4 comprises a chamber 8 defined by a top panel 8A, a bottom panel 8B, a first lateral panel 8C, a second lateral panel 8D, a rear panel 8E and a front panel 8F. The front panel 8F is placed opposite the rear panel 8E and defines a front side 4A of the robot controller cabinet 4.

Panels 8A, 8B, 8C, 8D, 8E, 8F together define the interior volume V8 of the chamber 8 of the robot controller cabinet 4.

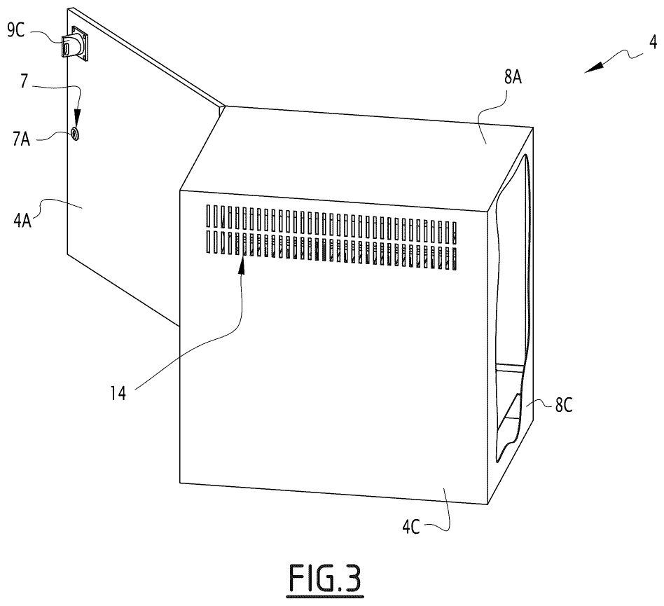

The front panel 8F comprises an opening 9A. The opening 9A is closed by a door 9B hinged to the front panel 8F. The door 9B can be operated from outside the robot controller cabinet 4 and has a disconnector 9C visible in FIG. 3. When the door 9B is placed in the open position as in FIGS. 2 and 3, it is possible to access the internal volume V8 of the chamber 8 from outside the cabinet. The door 9B supports a cam lock 7 comprising a handle 7A on the front side 4A of the robot controller cabinet and a bolt 7B enabling the door 9B to be held in the closed position by the actuation thereof. When the door 9B is closed, the internal volume V8 of the chamber 8 is sealed.

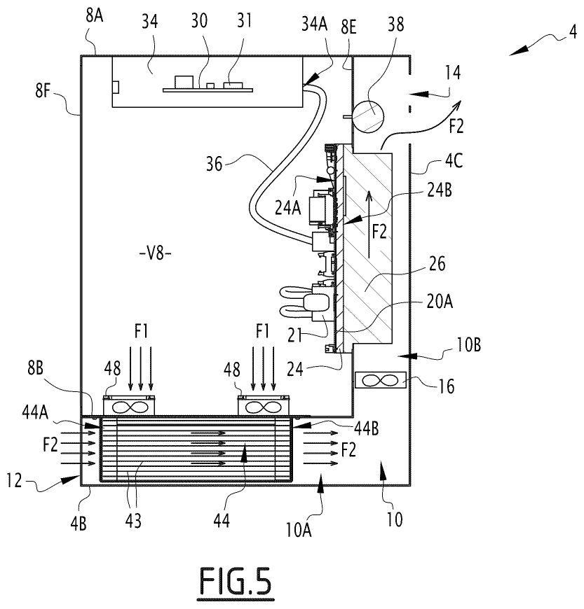

The robot controller cabinet 4 comprises a cooling channel 10, shown in FIG. 5. The cooling channel 10 comprises a first portion 10A defined between the bottom panel 8B of the chamber 8 and an outer panel 4B parallel to the bottom panel 8B. The outer parallel panel 4B defines a bottom of the robot controller cabinet 4. The cooling channel 10 comprises a second portion 10B defined between the rear panel 8E of the chamber 8 and an outer panel 4C parallel to the rear panel 8E. The outer parallel panel 4C defines a rear side of the robot controller cabinet 4. The cooling channel 10 is also delimited by the first lateral panel 8C and the second lateral panel 8D.

The two portions 10A and 10B of the cooling channel are contiguous and form a right angle at the junction thereof, at the bottom rear part of the robot controller cabinet 4.

The cooling channel 10 comprises an inlet opening 12 provided on the front side 4A of the robot controller cabinet 4 and an outlet opening 14 located at the end opposite the inlet opening of the cooling channel 10 and provided on the rear side 4C of the cabinet robot controller 4. The outlet opening 14 is in the form of a grid.

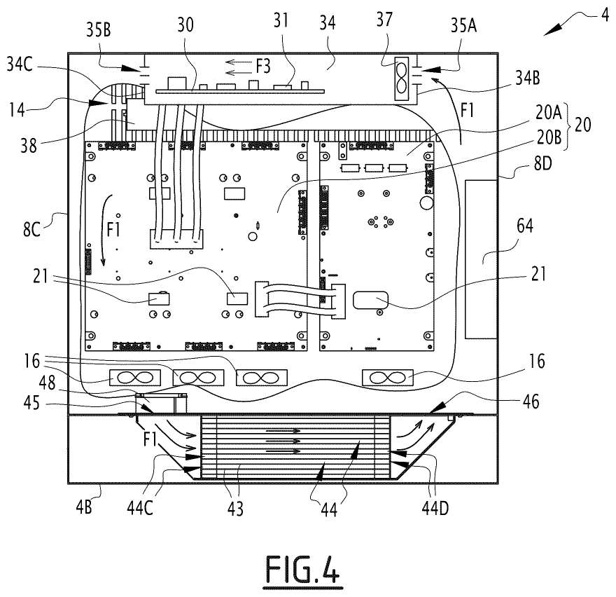

The cooling channel 10 comprises at least one fan 16 apt to draw in the outside air through the inlet opening 12 of the cooling channel 10 and to discharge said air to the outside through the outlet opening 14 of the cooling channel 10. Preferably, the fan 16 is placed in the second portion 10B of the cooling channel 10. Advantageously, the cooling channel 10 accommodates a plurality of fans 16, e.g. four fans 16 arranged over the entire width of the rear side 4C of the robot controller cabinet 4, as can be seen by cutaway in FIG. 4.

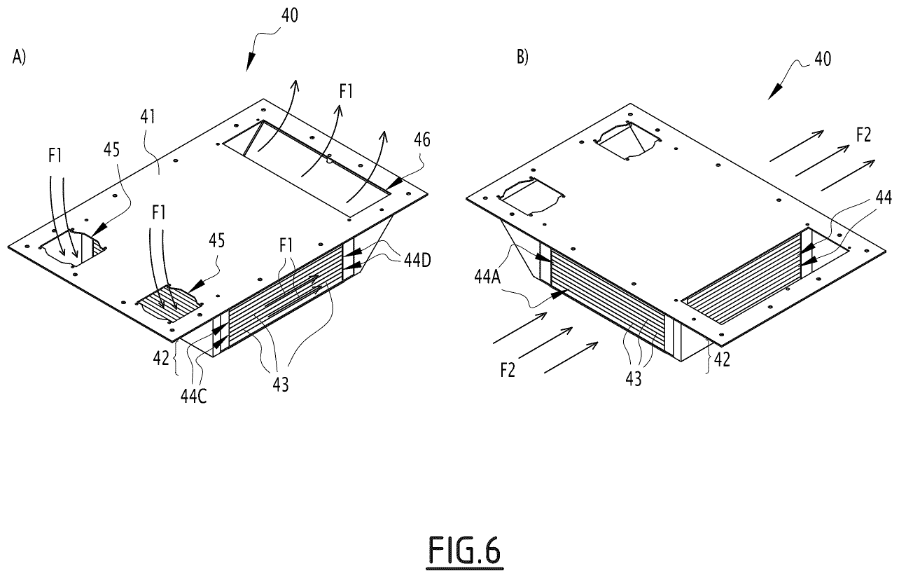

The robot controller cabinet 4 comprises an air-air cross-flow exchanger 40. The air-air cross-flow exchanger 40 is visible within the robot controller cabinet in FIGS. 2, 4 and 5 and in isolation in FIG. 6. The air-air cross-flow exchanger 40 is positioned in an opening (not shown) of the bottom panel 8B of the chamber 8, so that same is contained in the first portion 10A of the cooling channel 10, opposite the inlet opening 12 of the cooling channel 10.

The air-air cross-flow exchanger 40 comprises a support 41 and a stack 42 of plates 43. The support 41 closes hermetically the opening of the bottom panel 8B of the chamber 8.

The plates 43 are parallelepipedal metal sheets. The plates 43 are parallel to the support 41. As shown in FIG. 6, the plates 43 are spaced apart so as to leave a space 44 for the passage of an airflow. In other words, an airflow passage space 44 is defined between two adjacent plates 43.

For each airflow passage space 44, a front opening 44A parallel to the front side 4A of the robot controller cabinet 4, a rear opening 44B parallel to the rear side 4C of the robot controller cabinet 4, a first lateral opening 44C parallel to the first lateral panel 8C and a second lateral opening 44D parallel to the second lateral panel 8D, are defined.

The passage spaces 44 are alternately closed on the front openings 44A and rear openings 44B thereof or on the lateral openings 44C and 44D thereof. In other words, for two adjacent passage spaces 44, the first passage space 44 lets through the flow of a first airflow F1 from the first lateral opening 44C thereof to the second lateral opening 44D thereof and the second passage space 44 lets through the flow of a second airflow F2 from the front opening 44A thereof to the rear opening 44B thereof.

The alternating closures of the openings of the passage spaces 44 create two cooling circuits within the air-air cross-flow exchanger 40.

The first cooling circuit comprises two inlet openings 45 extending through the support 41 on the side of the lateral panel 8C and which are connected under the support 41, opposite the lateral openings 44C of the passage spaces 44. The first cooling circuit comprises an outlet opening 46 extending through the support 41 and extending parallel to the lateral panel 8D of the chamber 8. The first cooling circuit comprises all the passage spaces 44 for which the front openings 44A and the rear openings 44B are closed.

A fan 48 is positioned opposite each inlet opening 45, which delivers air from the internal volume V8 of the chamber 8 along the first cooling circuit. The fans 48 are positioned in the internal volume V8 of the chamber 8. The fans 48 generate in the first cooling circuit, the airflow F1, represented by arrows in FIGS. 4 and 6. Within the air-air cross-flow exchanger 40, the airflow F1 goes from the inlet openings 45 to the outlet opening 46, passing through passage spaces 44. In a variant (not shown), the first cooling circuit comprises a single inlet opening 45 extending through the support 41 and extending parallel to the lateral panel 8C of the chamber 8. In such case, a single fan 48 is advantageously provided.

In a variant (not shown), the fan or fans 48 are positioned opposite the outlet opening 46 of the first cooling circuit.

The second cooling circuit comprises an inlet opening formed by all the front openings 44A of the passage spaces 44. The inlet opening of the second cooling circuit is thus opposite the inlet opening 12 of the cooling channel 10. An outlet opening of the second cooling circuit is formed by all the rear openings 44B of the passage spaces 44. The outlet opening of the second cooling circuit is thus parallel to the inlet opening of the second cooling circuit. The outlet opening of the second cooling circuit opens into the first portion 10A of the cooling channel 10. The fans 16 positioned in the cooling channel 10 downstream of the air-air cross-flow exchanger 40 generate an airflow F2 within the air-air cross-flow exchanger 40, represented by arrows in FIGS. 5 and 6, going from the inlet opening of the second cooling circuit to the outlet opening of the second cooling circuit, passing through the passage spaces 44 the lateral openings 44C, 44D of which are closed.

In a variant (not shown), the fans 16 are positioned upstream of the air-air cross-flow exchanger 40 and generate an airflow F2 similar to the airflow described herein above.

Thereby, within the air-air cross-flow exchanger 40, the airflow F1, flowing within the first cooling circuit, flows perpendicularly to the airflow F2, flowing within the second cooling circuit.

The robot controller cabinet 4 comprises first electronic units 20. The first electronic units 20 are mounted on the rear panel 8E of the chamber 8, in the internal volume V8 of the chamber 8. The first electronic units 20 are e.g. a power supply unit 20A and a power unit 20B.

The first electronic power supply unit 20A is composed of one or a plurality of printed circuits comprising at least one electronic component with a high heat flux 21 symbolically represented in the figures, such as an insulated-gate field effect transistor (Metal Oxide Semiconductor Field Effect Transistor), a thyristor or DC-DC converter element that converts a DC source from a specified level of voltage to another different level of voltage. An electronic component with a high heat flux 21 is an electronic component which dissipates a high rate of heat flow given the dimensions thereof. Since such high power dissipation is concentrated on a small quantity of material, the dissipation leads to a significant increase in the temperature of the component. An electronic component with a high heat flux dissipates a rate of heat flow ranging e.g. from 20 Watt to 200 Watt.

The first electronic power unit 20B is e.g. an amplifier composed of printed circuits comprising at least one electronic component with a high heat flux 21 such as a switching module. Preferably, the switching module is an insulated-gate bipolar transistor.

The first electronic power unit 20B is apt to generate the currents in the motors of the robot arm 2 from the amplifier control instructions and the position information of the motors of the robot arm 2.

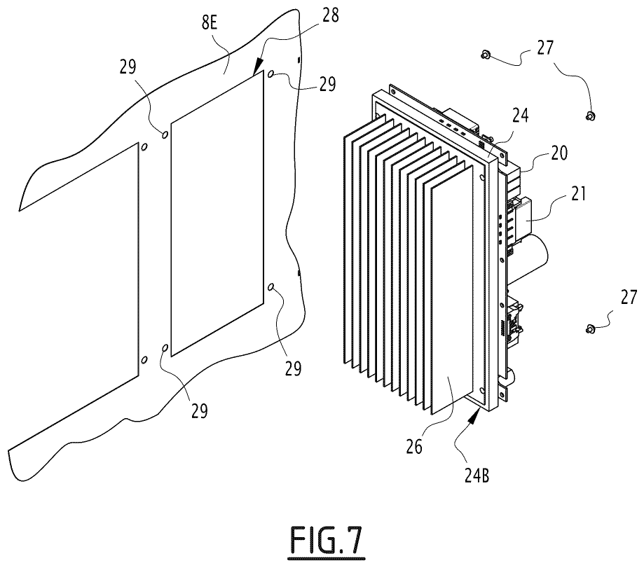

The first electronic units 20 comprise electronic components with a high heat flux 21. To improve the dissipation of the heat produced by the components with a high heat flux 21, each first electronic unit 20 is mounted on a first side 24A of an air-to-component heat exchanger 24. The air-to-component heat exchanger 24 supports on a second side 24B a cooling element 26 as can be seen in FIGS. 5 and 7. The additional element 26 is e.g. a set of blades. The cooling element 26 is made of a material with a high thermal conductivity such as e.g. aluminum.

The air-to-component heat exchanger 24 is positioned in an opening 28 of the rear panel 8E in such a way that the first electronic units 20 are inside the internal volume V8 of the chamber 8 and the cooling element 26 is inside the second portion 10B of the cooling channel 10. The air-to-component heat exchanger 24 is attached to the rear panel 8E by means of screws 27 fitted in tapped holes 29 and hermetically closes the opening 28 of the rear panel 8E. Advantageously, the air-to-component heat exchanger 24 is positioned in such a way that, in the cooling channel 10, the cooling element 26 is downstream of the fans 16.

The rear panel 8E comprises as many openings 28 as the first electronic units 20.

The robot controller cabinet 4 comprises a second electronic unit 30. For example, the second electronic unit 30 generates the control setpoints intended for the first electronic power units 20B which will allow the motors of the robot arm 2 to be properly actuated with in preparation for the action to be performed by the robot arm 2.

The second electronic unit 30 comprises at least one electronic component with a moderate heat flux 31. Preferably, the second electronic unit 30 is a computing unit and the electronic component with a moderate heat flux 31 is e.g. a processor. An electronic component with a moderate heat flux 31 is an electronic component that dissipates a low rate of heat flow but the temperature increase of which has to be limited for the component to function properly, i.e. which dissipates a rate of heat flow of less than 35 Watt.

The second electronic unit 30 is arranged inside a first rack unit 34. The first rack unit 34 is provided with a parallelepipedal frame. The first rack unit 34 is supported by the top panel 8A, inside the internal volume V8 of the chamber 8.

The first rack unit 34 is preferably mounted on rails (not shown) parallel to the lateral panels 8C, 8D of the chamber 8. The first rack unit 34 can slide on the rails, leading to an easy disassembly of the first rack unit 34 through the front door 9B of the robot controller cabinet 4.

The rack unit 34 comprises a first opening 34A provided on one of the faces thereof, preferably on the side opposite the rear panel 8E. The first opening 34A lets through the connection cables 36 passing from the second electronic unit 30 to the first electronic unit 20.

The first rack unit 34 comprises an internal fan 37 which generates an airflow F3 internal to the first rack unit 34. The internal airflow F3 flows between a first opening 35A provided on a first lateral side 34B of the first rack unit 34 opposite the lateral panel 8D toward a second opening 35B formed on a second lateral side 34C of the first rack unit 34 opposite the lateral panel 8C. The airflow F3 is superimposed on the airflow F1 which penetrates into the first rack unit 34 by means of the first opening 35A and emerges through the second opening 35B. The airflows F1 and F3 dissipate the heat produced inside the first rack unit 34, via the components with a moderate heat flux 31 toward the internal volume V8 of the chamber 8 which is larger than the volume of the rack unit 34 wherein the components with a moderate heat flux 31 are positioned.

The robot controller cabinet 4 comprises a second electronic unit 30 consisting of a filter unit 64 fastened to the lateral panel 8D. The filtering unit 64 is placed between the electrical network and the power supply unit 20A and has the function of filtering all electrical disturbances. Same contains electronic components with a moderate heat flux 31 such as e.g. a passive filtering component.

The robot controller cabinet 4 comprises a braking resistor 38. The braking resistor 38 is mounted on the rear panel 8E of the chamber 8 in the cooling channel 10. In other words, the braking resistor 38 which is visible in FIGS. 2 and 4, is outside the internal volume V8 of the chamber 8. The braking resistor 38 is arranged opposite the outlet opening 14 of the cooling channel 10. The braking resistor 38 is supplied by the first electronic power unit 20B when the motors of the robot arm 2 give back energy. In other words, the braking resistor 38 dissipates the excess energy produced by the first electronic power unit 20B.

When the robot R is in operation, the components with a high heat flux 21 produce heat that has to be dissipated to allow the components with a moderate heat flux 31 to function properly.

The fans 48 generate an airflow F1. The airflow F1 enters the air-air cross-flow exchanger 40 via the openings 44C of the passage spaces 44 and leaves via the openings 44D. The airflow F1 then enters the chamber 8 through the outlet opening 46. In the internal volume V8 of the chamber 8, the airflow F1 follows the lateral panel 8D then the first rack unit 34, then the lateral panel 8C as far as the opening 45 at the bottom panel 8B. The airflow F1 thus performs a cycle within the internal volume V8 of the chamber 8.

The airflow F3 inside the first rack unit 34 has the same direction as the airflow F1.

The airflow F1 provides the heat dissipation of the heat generated by electronic components with moderate heat flux 31. The airflow F1 is cooled by the airflow F2 during the passage thereof through the air-air cross-flow exchanger 40.

The fans 16 of the cooling channel 10 generate the airflow F2 from the inlet opening 12 of the cooling channel 10 to the outlet opening 14 of the cooling channel 10. The airflow F2 passes through the passage spaces 44 within the air-air cross-flow exchanger 40. Since the air-air cross-flow exchanger 40 is placed at the inlet of the cooling channel 10, the temperature of the airflow F2 at the inlet of the air-air cross-flow exchanger 40 is the temperature of the ambient air and is lower than the desired air temperature in the chamber 8, which is on the order of 55 degrees Celsius. The airflow F2 is apt to cool the airflow F1. After passing through the air-air cross-flow exchanger 40, the airflow F2 is in contact in the cooling channel 10 of the cooling elements 26 of the air-to-component heat exchangers 24 the temperature of which may reach 85 degrees Celsius. The heat generated by the components with a high heat flux 21 is collected by the air-to-component heat exchangers 24 and is dissipated by the airflow F2 in the cooling channel 10 because the air temperature of the airflow F2 at the air-to-component heat exchangers 24 is lower than the temperature of the cooling elements 26 of the air-to-component heat exchangers 24.

As the airflow F2 crosses the airflow F1 and is in contact with the cooling elements 26 of the air-to-component heat exchangers 24, same ensures both the heat dissipation of the heat generated by the electronic components with a high heat flux 21 and the heat dissipation of the heat generated by the electronic components with a moderate heat flux 31.

Advantageously, in some applications where it may be necessary to stack a plurality of 4 robot controller cabinets, the flow of the airflow F2 ensures that the heat production of a first robot controller cabinet 4 discharged through the outlet opening 14 does not impact the cooling of a second cabinet 4 positioned above or below.

The combined action of the airflows F1 and F2 serves to dissipate the heat generated by the components with a high heat flux 21 and to maintain in the internal volume V8 of the chamber 8 a correct operating temperature for the elements with a moderate heat flux 31.

By means of the air-air cross-flow exchanger 40 which allows heat exchange between the two airflows F1 and F2, the heat produced by the first electronic units 20 affects the second electronic units 30 in a limited way.

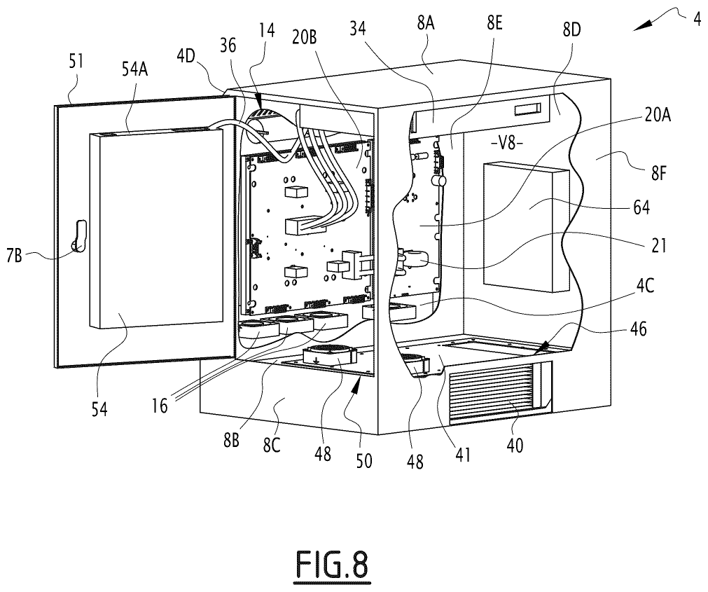

In the second embodiment shown in FIG. 8, elements similar to the elements of the first embodiment bear the same references. If a reference is used hereinafter in the description without being shown on FIG. 8 or is shown in FIG. 8 without being mentioned in the description, the reference refers to the same element as the element bearing the same reference in the first embodiment. Hereinafter, it is mainly described what distinguishes the second embodiment from the first embodiment.

In the second embodiment, the lateral panel 8C comprises an opening 50 closed by a lateral door 51. The lateral door 51 gives access, in the open position, to the internal volume V8 of the chamber 8.

The front panel 8F has only one opening corresponding to the inlet opening 12 of the cooling channel 10.

The outlet opening 14 of the cooling channel 10 is provided on an oblique side 4D of the robot controller cabinet 4. The oblique panel 4D extends between the top panel of the chamber 8A and the rear side 4C of the robot controller cabinet 4.

The first rack unit 34 is preferentially mounted on rails (not shown) parallel to the front panel 8F and rear panel 8E of the chamber 8. The first rack unit 34 can slide on the rails to an easy disassembly of the first rack unit 34 through the lateral door 51 the robot controller cabinet 4.

The door 51 comprises on the internal side 51A thereof, opposite the internal volume V8 of the chamber 8, a second slide 54. A second electronic unit 30 is positioned inside the second rack unit 54. The second rack unit 54 comprises an opening on one of the sides thereof, preferably on the top side 54A thereof opposite the top panel 8A of the chamber 8, which lets through a connection cable 36 toward the first 20 and second 30 electronic units located outside the rack unit 54.

The second electronic units 30 are thus contained in a first rack unit 34 and/or a second rack unit 54.

In other words, the second electronic unit 30 is placed on the top panel 8A of the chamber 8 and/or is supported by the door 51 of the lateral panel 8C.

The airflow F1 generated to ensure the heat dissipation of the electronic components with a moderate heat flux 31 performs a cycle in the chamber 8 similar to the cycle described hereinabove. In the internal volume V8 of the chamber 8, the airflow F1 penetrates through the outlet opening 46, then follows the lateral panel 8D, then the first rack unit 34, then the second rack unit 54 as far as the openings 45 at the bottom panel 8B.

In a variant (not shown), the filtering unit 64 is fastened to the lateral panel 8C and the lateral panel 8D comprises an opening 50 closed by a door 51.

The advantages of the invention result from the use of an air-air cross-flow exchanger 40 which makes it possible to set up an airflow F1 inside a single chamber 8 which travels through lateral panels 8C and 8D and a top panel 8A and an open airflow F2 perpendicular to the flow of air F1 and which travels through a rear panel 8E. It is then possible to have in the same chamber 8, two distinct cooling regimes. First electronic units 20 mounted on the rear panel 8E of the chamber 8 and comprising components with a high heat flux 21 are mainly cooled by the airflow F2 and second electronic units 30 mounted on the lateral panel or panels 8C or 8D or the top panel 8A and comprising electronic components with a moderate heat flux 31, are mainly cooled by the airflow 1. The airflow 1 serves to maintain the air in the chamber 8 at a temperature compatible with the operation of electronic components with a moderate heat flux equipping the second electronic units 30 but also the first electronic units 20 as may be the case.

Insofar as is technically feasible, the embodiments and variants mentioned hereinabove may be combined with one another.

Robot controller cabinet and robot comprising such a cabinet The present invention relates to a robot controller cabinet comprising: a chamber (8); first and second electronic units (20, 30) comprising an electronic component with a high heat flux (21) and with a moderate heat flux, respectively; a cooling channel comprising a fan (16) and an inlet (12) provided on a front side (4A) of the cabinet; an air-to-component heat exchanger supporting a cooling element.

According to the invention, an air-air cross-flow exchanger is arranged in the channel and comprises: a first cooling circuit with an inlet and an outlet passing through a bottom panel (8B) of the chamber; a second cooling circuit with a parallel inlet and outlet, the inlet opposite the inlet of the channel; a fan (48), generating in the first cooling circuit an airflow perpendicular to an airflow generated in the second cooling circuit by the fan of the channel.

1. A robot controller cabinet comprising:
a chamber defined by a top panel, a bottom panel, two lateral panels, a rear panel, and a front panel arranged opposite the rear panel and defining a front side of the robot controller cabinet,
the chamber and comprising at least one electronic component with a high heat flux,
at least one second electronic unit mounted on one or more of the lateral panels or the top panel inside the chamber and comprising at least one electronic component with a moderate heat flux,
a cooling channel comprising:
an inlet opening,
at least one fan apt to draw in outside air through the inlet opening of the cooling channel and discharging same outwards through an outlet opening located at the end opposite the inlet opening of the cooling channel,
at least one air-to-component heat exchanger associated with a first electronic unit and accommodating on a first side, at least one electronic component with a high heat flux and supporting, on a second side, at least one cooling element, arranged in the cooling channel, wherein:
the cooling channel comprises
a first portion defined between the bottom panel of the chamber and an outer parallel panel defining a bottom of the robot controller cabinet,
a second portion contiguous to the first portion, located between the rear panel of the chamber and an outer parallel panel defining a rear side of the robot controller cabinet,
the inlet opening of the cooling channel is provided on the front side of the cabinet,
an air-air cross-flow exchanger is arranged in the cooling channel and comprises:
a first cooling circuit having an inlet opening through the bottom panel of the chamber and an outlet opening through the bottom panel of the chamber,
a second cooling circuit having an inlet opening opposite the inlet opening of the cooling channel and an outlet opening parallel to the inlet opening of the second cooling circuit, being arranged at the opposite end of the air-air cross-flow exchanger and opening into the cooling channel,
at least one fan, located inside the chamber opposite the inlet opening or the outlet opening of the first cooling circuit of the air-air cross-flow exchanger, generates, in the first cooling circuit, an airflow perpendicular to an airflow generated in the second cooling circuit by the fan of the cooling channel.

2. The robot controller cabinet according to claim 1, wherein the fan of the cooling channel is arranged downstream of the air-air cross-flow exchanger, upstream of the air-to-component heat exchanger and in the second portion of the cooling channel.

3. The robot controller cabinet according to claim 1, wherein the first electronic unit is an amplifier and the component with a high heat flux is a switching module, preferably an insulated-gate bipolar transistor.

4. The robot controller cabinet according to claim 1, wherein the first electronic unit is a power supply and the component with a high heat flux is an insulated-gate field effect transistor or a thyristor or a DC-DC converter element that converts a DC source to a specified level of voltage into another different level of voltage.

5. The robot controller cabinet according to claim 1, wherein the second electronic unit is a computing unit and the component with a moderate heat flux is a processor.

6. The robot controller cabinet according to claim 1, wherein the second electronic unit is a filtering unit and the component with a moderate heat flux is a passive filtering component.

7. The robot controller cabinet according to claim 1, wherein the robot controller cabinet comprises a braking resistor, mounted on the rear panel of the chamber in the cooling channel downstream of the air-to-component heat exchanger, configured to dissipate excess energy produced by the first electronic unit.

8. The robot controller cabinet according to claim 1, wherein the outlet opening of the cooling channel is provided on the rear side of the robot controller cabinet.

9. The robot controller cabinet according to claim 1, wherein the second electronic unit is arranged inside a first rack unit supported by the top panel of the chamber, the first rack unit comprising a first opening, arranged opposite a lateral side of the chamber, and a second opening arranged opposite the other lateral side of the chamber.

10. The robot controller cabinet according to claim 1, wherein a lateral panel of the chamber comprises an opening closed by a door and the second electronic unit is placed on the top panel of the chamber and/or is supported by the door of the lateral panel.

11. A multi-axis robot comprising:
a robot arm articulated to at least two degrees of freedom,
a robot controller cabinet according to claim 1,
cables connecting the robot arm to the robot controller cabinet.
